(19) United States
(12) Patent Application Publication
(10) Pub. No.: US 2012/0112063 A1
(43) Pub. Date: May 10, 2012

(54) METHOD AND APPARATUS FOR GENERATING THREE-DIMENSIONAL IMAGE DATA

(76) Inventor: Andreas Schertel, Aalen (DE)

(21) Appl. No.: 13/259,469

(22) PCT Filed: Mar. 18, 2010
(86) PCT No.: PCT/EP2010/053561

§ 371 Date: Jan. 6, 2012

(30) Foreign Application Priority Data
Mar. 26, 2009 (DE) 10 2009 001910.3

(51) Int. Cl. H01J 37/26; B32B 3/00

(52) U.S. Cl. 250/307; 250/310; 428/195.1

(57) ABSTRACT

A method and an apparatus for generating three-dimensional image data of a sample are disclosed. A first particle beam is provided for exposing a surface and a second particle beam is provided for generating an image of the surface are used. By moving the sample, it suffices if the first particle beam and/or the second particle beam are initially focused once on a surface of the sample that has already been exposed. Because all further exposed surfaces are always located in the same position, refocusing the first particle beam and/or the second particle beam is no longer required.

The invention relates to a method and an apparatus for generating three-dimensional image data of a sample.

Generating three-dimensional image data of a sample (also called object) of interest is highly desirable in many fields, particularly in the biosciences. On the basis of the three-dimensional image data, which enable a three-dimensional representation of a sample, numerous analyses of the sample can be carried out.

A method for generating three-dimensional image data of a sample is already known from the prior art. In this known method, by means of a first particle beam in the form of an ion beam, a layer of the sample is removed in such a way that a surface of the sample is exposed. A second particle beam in the form of an electron beam is subsequently fed to the exposed surface. When the second particle beam impinges on the surface, interaction particles (for example secondary electrons or backscattered electrons) arise, which are detected. Detection signals arising during the detection are used for imaging. In this way, image data with regard to the exposed surface are obtained, which are stored. By repeatedly successively performing the abovementioned method steps and subsequently combining the image data of the individual exposed surfaces, it is possible to obtain three-dimensional image data and hence a three-dimensional representation of the sample.

In a further known method, both a first particle beam (ion beam) and a second particle beam (electron beam) are likewise used. The first particle beam is guided substantially perpendicularly to a marking surface of the sample to be examined. Two longitudinal markings are applied on the marking surface, which are arranged in a V-shaped manner with respect to a longitudinal axis of the sample and intersect at a point on the marking surface of the sample. Furthermore, it is provided that, by means of the first particle beam, a layer of the sample is removed by scanning the first particle beam perpendicularly to the longitudinal axis of the sample. A surface oriented perpendicularly to the longitudinal axis of the sample is exposed as a result. In a further step, the second particle beam impinges on the exposed surface. The interaction particles that arise in this case are detected. The detection signals that arise during the detection are used for imaging, and the image data obtained in this way are stored. The abovementioned method steps are repeated in order to expose further surfaces of the sample to be examined and to obtain image data of the further surfaces. In a subsequent method step, the stored image data of the different exposed surfaces are combined to form a three-dimensional image data record of the sample.

With regard to the abovementioned prior art, reference is made to U.S. Pat. No. 7,312,448 B2 in particular.

The known methods are well suited to numerous applications. However, considerations have revealed that they are not as well suited to examining a sample having a relatively large volume. The possibility of analyzing a sample having a relatively large volume is desirable, however, in many scientific fields. By way of example, in microbiology and human medicine, in particular, there is interest in examining a sample embodied as a cube having an edge length of 200 μm or greater. A sample of this type is created, for example, during an examination of a human brain, the unit cell of which has an edge length of 200 μm. The volume of this unit cell is therefore (200 μm)³. In the known methods, however, such a volume can only by examined with a relatively low resolution by means of an ion beam and electron beam. With the known methods, however, there is the possibility of dividing the sample volume to be examined into smaller examination regions and examining the respective examination regions individually. However, since the examination regions have different positions and removed layers can have different thicknesses, it is necessary that, firstly, the ion beam and/or the electron beam have to be constantly refocused and, secondly, parameters for example for the correction of astigmatism have to be corrected. The refocusing and correction of the parameters have to be effected relatively often. The measurement of a sample having a large volume by means of these known methods is therefore relatively time-consuming.

Therefore, the invention addresses the problem of specifying a method and an apparatus for generating three-dimensional image data of a sample by means of which even a sample having a relatively large volume can be examined sufficiently well.

According to the invention, this problem is solved by means of a method comprising the feature of claim 1. A computer program product comprising an executable program code for carrying out the method according to the invention is provided by the features of claim 18. Furthermore, the invention relates to a sample comprising the features of claim 19, and to a particle beam device for carrying out the method according to the invention comprising the features of claim 23. Further features of the invention emerge from the following description, the accompanying claims and/or the accompanying drawings.

The method according to the invention for generating three-dimensional image data has a plurality of steps. Thus, provision is made for moving a sample (that is to say an object to be examined) arranged on a sample carrier embodied in movable fashion by means of the sample carrier in the direction of a longitudinal axis of the sample. By way of example, provision is made for moving the sample continuously. The longitudinal axis preferably lies in a first plane, which is arranged perpendicular or substantially perpendicular to a second plane, in which a first particle beam is fed to the sample.

The sample carrier is embodied as a sample stage, for example, wherein the movable embodiment of the sample stage is ensured by a plurality of movement elements of which the sample stage is composed. The movement elements enable the sample stage to be moved in at least one specific direction. In particular, sample stages are provided which have a plurality of translational movement elements (for example approximately three to four translational movement elements), and also a plurality of rotational movement elements (for example two to three rotational movement elements). In particular, it is provided that the sample carrier can be moved along three axes perpendicular to one another. Furthermore, it is provided that the sample carrier is embodied such that it is rotatable about a first rotation axis and about a second rotation axis, which is perpendicular to the first rotation axis.

In a further method step, in the method according to the invention, a first particle beam is guided to the sample. By means of the first particle beam, a first layer is removed from the sample in such a way that a first surface of the sample is exposed. A second particle beam is in turn fed to the first surface, said second particle beam being focused onto the first surface of the sample. Upon feeding the second particle beam onto the first surface of the sample, interaction particles (for example secondary electrons or backscattered electrons) and/or interaction reactions (for example X-rays) arise. These are detected and used for acquiring first image data of the sample, which reproduce properties of the first surface. The first image data are stored.

In a further method step of the method according to the invention, a second layer of the sample is removed by means of the first particle beam, wherein the second layer has the first surface. As a result of the second layer being removed, a second surface of the sample is exposed. Afterward, the second particle beam is guided onto the second surface of the sample. By detecting interaction particles and/or interaction reactions that arise as a result of feeding the second particle beam onto the second surface of the sample, second image data of the sample are acquired, wherein the second image data reproduce properties of the second surface. The second image data are stored. Afterward, in an analysis unit by way of example, three-dimensional image data of the sample are calculated by means of the stored first image data and the stored second image data.

In a further embodiment of the method, it is provided that the sample arranged on the sample carrier embodied in movable fashion is moved by means of the sample carrier in the direction of the longitudinal axis of the sample to a first predeterminable position of the sample. In this case, the first predeterminable position is chosen by a coordinate KX1 in an x-direction, a coordinate KY1 in a y-direction and by a coordinate KZ1 in a z-direction in a predetermined coordinate system. The coordinate system has three axes respectively arranged perpendicular to one another (namely an x-axis, a y-axis and a z-axis). The first predeterminable position is chosen suitably such that the first particle beam can be guided to the sample. In a further method step, the first particle beam is guided to the sample. By means of the first particle beam, the first layer is removed from the sample in such a way that the first surface of the sample is exposed. The second particle beam is in turn fed to the first surface, said second particle beam being focused onto the first surface of the sample. Upon feeding the second particle beam onto the first surface of the sample, the above-mentioned interaction particles and/or interaction reactions arise. These are detected and used for acquiring the first image data of the sample, which reproduce the properties of the first surface. The first image data are stored.

In a further method step of this exemplary embodiment, the sample is moved in the direction of the longitudinal axis of the sample by means of the sample carrier into a second predeterminable position of the sample. In this case, the second predeterminable position is chosen by a coordinate KX2 in the X-direction, a coordinate KY2 in the y-direction and by a coordinate KZ2 in the z-direction in the abovementioned coordinate system. The second layer of the sample is then removed by means of the first particle beam, wherein the second layer has the first surface. As a result of the second layer being removed, the second surface of the sample is exposed. Afterward, the second particle beam is guided onto the second surface of the sample. By detecting the interaction particles and/or interaction reactions that arise as a result of feeding the second particle beam onto the second surface of the sample, the second image data of the sample are acquired, wherein the second image data reproduce properties of the second surface. The second image data are stored. Afterward, in the analysis unit, by way of example, the three-dimensional image data of the sample are calculated by means of the stored first image data and the stored second image data.

A further embodiment of the method according to the invention basically corresponds to the above-described exemplary embodiment, wherein the order of some method steps is different in the following embodiment of the method. Firstly, the first particle beam is guided to the sample arranged on the sample carrier embodied in movable fashion. The sample carrier corresponds, for example, to the sample carrier already explained further above. Afterward, the first layer of the sample is removed by means of the first particle beam, such that the first surface of the sample is exposed. Afterward, the sample is moved by means of the sample carrier in the direction of the longitudinal axis of the sample to a first predeterminable position of the sample. With regard to the definition of the first predeterminable position, reference is made to further above. Furthermore, the second particle beam is focused onto the first surface of the sample. Afterward, the first image data of the sample are acquired by detecting the interaction particles and/or interaction reactions. The first image data are stored. Afterward, the second layer of the sample is removed by means of the first particle beam, wherein the second layer has the first surface and whereby the second surface of the sample is exposed. The sample is then moved in the direction of the longitudinal axis of the sample by means of the sample carrier into the second predeterminable position of the sample. With regard to the definition of the second predeterminable position, reference is made to further above. Afterward, the second particle beam is fed onto the second surface of the sample. The second image data of the sample, which indicate properties of the second surface, are acquired by detecting the interaction particles and interaction reactions that arise as a result of the second particle beam being fed onto the second surface of the sample. The second image data are stored. Both the first image data and the second image data are then used for calculating three-dimensional image data of the sample.

A further embodiment of the method provides for storing the first predeterminable position and/or the second predeterminable position, for example when storing the first image data and/or the second image data.

In each of the embodiments of the methods, it is provided, for example, that a layer thickness of the first layer to be removed and/or of the second layer to be removed is predetermined. Furthermore, it can be provided that the first predeterminable position and the second predeterminable position are identical. By way of example, what is involved is a position of the sample in which the first particle beam impinges on an edge (that is to say on an outer boundary) of the sample, wherein the edge is arranged perpendicular or substantially perpendicular to the longitudinal axis of the sample. The edge is, for example, an edge of a cubic sample.

The method according to the invention is based on the concept of setting the position of the sample relative to the first particle beam and the second particle beam by moving the sample along the longitudinal axis thereof in such a way that both good removal of layers of the sample and good production of an imaging of an exposed surface are possible. Since a sample carrier embodied in movable fashion can move the sample in the direction of the longitudinal axis of the sample over large distances, it is possible to analyze a sample having a large volume. By way of example, said sample can be embodied in cubic fashion with an edge length of 200 μm or greater.

It is provided, in particular, that the layers to be removed have identical layer thicknesses, as already explained briefly above. As an alternative or in addition thereto, it can also be provided that the surfaces to be examined are moved repeatedly into a very specific position by means of a movement of the sample carrier, as likewise explained briefly above. To put it another way, the invention makes it possible for an exposed surface to be situated at the same position relative to the first particle beam and the second particle beam. Consequently, it suffices to focus the first particle beam and/or the second particle beam initially once onto a surface of the sample which is situated in the specific position relative to the first particle beam and/or the second particle beam. Since all further exposed surfaces are always arranged at this position, it is therefore no longer necessary to refocus the first particle beam and/or the second particle beam. The method makes it possible for the first particle beam and/or the second particle beam always to be used in the same plane. A change or correction of parameters (for example with regard to the focusing of the first particle beam and the second particle beam or with regard to correction of astigmatism) is not necessary. Basically, the invention makes it possible to use stationary particle beams, that is to say particle beams which can always be inserted into one and the same plane. Consequently, since possible imaging aberrations are also stationary, it is not necessary to correct or change parameters. This leads to shorter measurement times in comparison with the prior art.

In a further exemplary embodiment of the methods according to the invention, the first particle beam is fed to the sample in a plane arranged perpendicular to the longitudinal axis of the sample. Furthermore, it is provided that the first particle beam is scanned over the sample. To put it another way, the first particle beam is fed to the sample parallel to that surface on which the second particle beam impinges and the image data of which are determined.

In the methods according to the invention it can be provided that a particle-optical axis of a particle beam device which provides the second particle beam forms an angle with the first surface or the second surface. In this exemplary embodiment, the second particle beam is accordingly incident obliquely on the first surface and/or the second surface. In a further exemplary embodiment, the second particle beam is scanned over the first surface and/or the second surface.

In a further exemplary embodiment of the methods according to the invention, it is provided that in the course of acquiring the first image data, at least one first image data group and at least one second image data group are acquired. In this case, the first image data group is assigned to a first region of the first surface. The second image data group is assigned to a second region of the first surface. Assignment of the first image data group to the first region of the first surface is understood to mean that the first image data group contains image data of the first region. The same correspondingly applies to the second image data group. After acquiring the first image data group and the second image data group, it is possible to combine the first image data group and the second image data group in a mosaic-like manner to form the first image data. In a further exemplary embodiment of the methods according to the invention, the identical situation is provided alternatively or additionally for the second surface. Thus, in this exemplary embodiment it is provided that in the course of acquiring the second image data, at least one third image data group and at least one fourth image data group are acquired, wherein the third image data group is assigned to a third region of the second surface, and wherein the fourth image data group is assigned to a fourth region of the second surface. With regard to the definition of “assignment”, reference is made to further above. In this exemplary embodiment, the third image data group and the fourth image data group are combined in a mosaic-like manner to form the second image data.

The acquisition of image data groups in accordance with the abovementioned exemplary embodiments has the following background. The image data of the individual surfaces, which are composed of pixels, are scanned step by step (that is to say pixel by pixel) and stored. The number of pixels is limited, however. Since the resolution capability of scanning units used for scanning is limited (it is not possible to perform infinitely small steps, rather the steps always have a finite size), the resolution with which the image data are determined and stored is therefore limited. Consequently, the number of pixels that the image data are allowed to contain is limited. If a pixel size of 5 nm is assumed, then a surface to be examined which extends along an x-axis and a y-axis (the x-axis and y-axis are arranged perpendicular to one another) over 200 μmin each case has more than 40 000 pixels both along the x-axis and along the y-axis. However, the resolution capability of scanning units which are currently known to the applicant is only approximately 4000 to 8000 pixels in each direction. By means of the above-described embodiments of the methods according to the invention, image data groups having a resolution of less than the maximum resolution can be acquired without any problems and combined in a mosaic-like manner to form the first and second image data.

In a further exemplary embodiment of the methods according to the invention, the second particle beam is guided to a first beam position on a first surface region and/or a second beam position on a second surface region. The first surface region and the second surface region are formed for example at an individual surface. They thus form part of said individual surface. In addition, provision is made for reading at least one correction value from a correction map in a manner dependent on the first beam position and/or the second beam position, in order to correct the focusing of the second particle beam on the first surface region and/or the second surface region. This is advantageous particularly during the mosaic-like combination, since the focusing of the second particle beam during scanning over a somewhat larger surface can indeed vary somewhat. Furthermore, it is provided that the second particle beam also in a manner dependent on the first beam position on the first surface region and/or the second beam position on the second surface region is already automatically corrected with regard to astigmatism and further correctable parameters.

In a further exemplary embodiment of the methods according to the invention, at least one line-like first marking running non-parallel (that is to say at an angle deviating from 0° and 180°) to the longitudinal axis of the sample is provided, with which the first predeterminable position of the sample and/or the second predeterminable position of the sample are determined. By way of example, as the first marking, a plurality of punctiform or hole-type individual markings are provided, which are arranged in the form of a line. However, it is expressly pointed out that the invention is not restricted to punctiform or hole-type individual markings. Rather, any form of individual markings which are suitable for a line-type arrangement can be used.

In addition or as an alternative thereto it is provided that at least one second marking is provided which runs parallel to the longitudinal axis of the sample and which is likewise used for determining the first predeterminable position of the sample and/or the second predeterminable position of the sample. By way of example, the second marking has at least one line which runs parallel to the longitudinal axis and which is arranged at an edge of the sample to be examined or at least runs in the direction of said edge.

In yet another exemplary embodiment of the methods according to the invention, the first marking and/or the second marking are/is introduced into the sample by means of the first particle beam and/or the second particle beam. By way of example, by means of an ion beam, cutouts are introduced into a marking surface of the sample, said cutouts being line-like. As an alternative thereto, provision is made for producing the first marking and/or second marking by means of particle beam deposition. The marking surface into which the cutouts are introduced is arranged perpendicular to the first surface and the second surface to which the second particle beam is guided. Alternatively or additionally provision is made for providing the first marking and/or the second marking with a contrast agent.

One exemplary embodiment of the methods according to the invention provides a particular form of the position determination of the first predeterminable position and/or of the second predeterminable position of the sample. In this exemplary embodiment, the first particle beam is provided in the plane arranged perpendicular to the longitudinal axis of the sample. Interaction particles that arise on account of the interaction of the first particle beam with matter are subsequently detected. As a result of the sample being moved along the longitudinal axis of the sample, the sample edge already mentioned further above is moved. The sample is moved until a predeterminable threshold value is exceeded during the detection of interaction particles. In this case, it is ensured that the edge of the sample is arranged exactly at the position at which the first particle beam is situated.

In a further embodiment of the methods according to the invention, an ion beam is fed as the first particle beam. Alternatively or additionally it is provided that an electron beam is fed as the second particle beam.

The invention also relates to a computer program product comprising an executable program code which, when executed in a computer processor, executes the steps of a method having at least one of the abovementioned features or a combination of abovementioned features.

The invention also relates to a sample which can be analyzed by means of a particle beam device (that is to say an object to be examined). The sample has a longitudinal axis, wherein reference is made to above with regard to the definition of the longitudinal axis. Furthermore, the sample is provided with at least one first marking which runs non-parallel (that is to say at an angle deviating from 0° and 180°) to the longitudinal axis of the sample. By way of example, the first marking is arranged at an angle of 78° to 87° or of 80° to 85° with respect to the longitudinal axis. If the longitudinal axis is arranged perpendicular to the plane in which, for example, the first particle beam described above impinges on the sample (that is to say the cutting plane in which layers are removed and surfaces are exposed), then this arrangement can also be expressed in such a way that the first marking is arranged at an angle of 3° to 12° or of 5° to 10° with respect to said cutting plane. The first marking itself has a plurality of punctiform or hole-type individual markings, which are line-like. In particular, provision is made for arranging a grating on a surface of the sample, said grating consisting of a plurality of individual markings arranged in line-like fashion.

On account of the abovementioned markings it is possible to determine the position of the sample particularly well. Consequently, it is possible to assign image data acquired for numerous surfaces of the sample to a very specific position of the sample, such that combination of the image data of the large number of surfaces to form a three-dimensional image data record of the sample is possible particularly well. Since, moreover, the above-mentioned markings can be arranged practically “endlessly” on the sample (an extent in the longitudinal direction of the sample is only limited by the length of the sample itself), samples of any desired length can be examined. This is explained in greater detail further below.

In a further embodiment, the sample according to the invention also has at least one second marking running parallel to the longitudinal axis of the sample. It comprises, for example, line structures arranged in such a way that they define a 10-fold or 100-fold distance between a first marking and an original cutting plane. This is also explained in greater detail further below.

The abovementioned individual markings have diameters of 10 nm to 100 nm, for example. In a further embodiment, diameters of 15 nm to 60 nm are provided, for example. In a further embodiment, a diameter of approximately 25 nm is provided. Considerations have revealed that the diameter can be greater than the desired resolution along the longitudinal axis of the sample (depth resolution). By way of example, the diameter given a depth resolution of 5 nm amounts to the aforementioned 25 nm.

In yet another exemplary embodiment, the first marking and/or the second marking are/is provided with a contrast agent, for example platinum. In this way, the individual markings become particularly readily discernible by imaging by means of the second particle beam.

It is pointed out that the invention is not restricted to the abovementioned configurations of the markings explained above. Rather, any marking which enables a position determination of a sample and the measurement of a removed layer of a sample is suitable.

The invention also relates to a particle beam device for carrying out a method comprising at least one of the abovementioned features or a combination of above-mentioned features. The particle beam device according to the invention is provided with at least one sample carrier for receiving a sample, wherein the sample carrier is embodied in movable fashion. The sample carrier can have one of the features already mentioned further above. In addition, the particle beam device has at least one first means for generating a first particle beam and at least one second means for generating a second particle beam. By way of example, the first means is an ion beam column, whereas the second means is embodied as an electron beam column. Furthermore, at least one first objective lens for focusing the first particle beam onto the sample and at least one second objective lens for focusing the second particle beam onto the sample are provided. Furthermore, the particle beam device has at least one control unit with a processor, in which a computer program product is loaded, which has already been mentioned further above. Furthermore, the particle beam device according to the invention can be provided with a sample having at least one of the abovementioned features or a combination of the abovementioned features.

The invention is explained in greater detail below on the basis of exemplary embodiments by means of figures, in which:

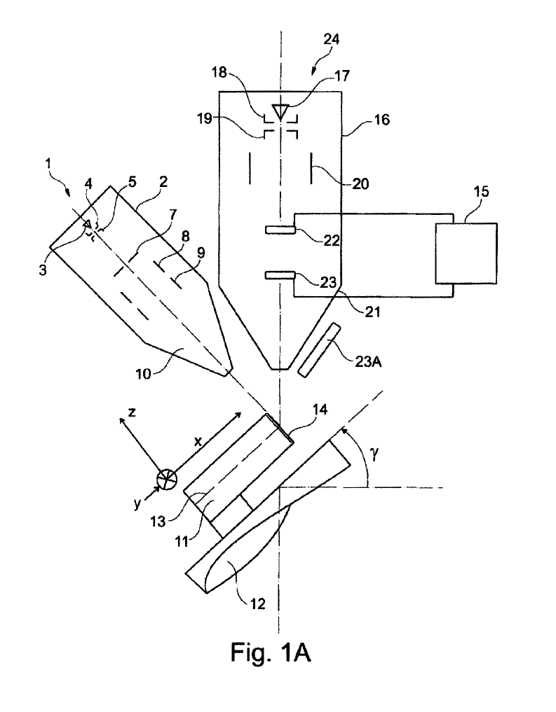

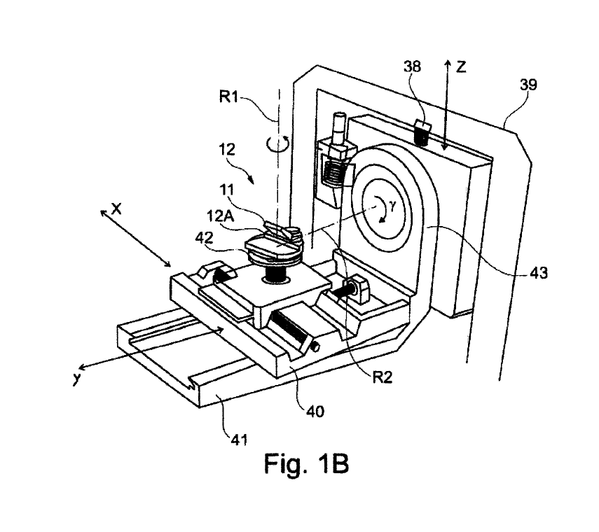

FIG. 1A shows a schematic illustration of a particle beam device with two particle beam columns;

FIG. 1B shows a schematic illustration of the arrangement of a sample carrier;

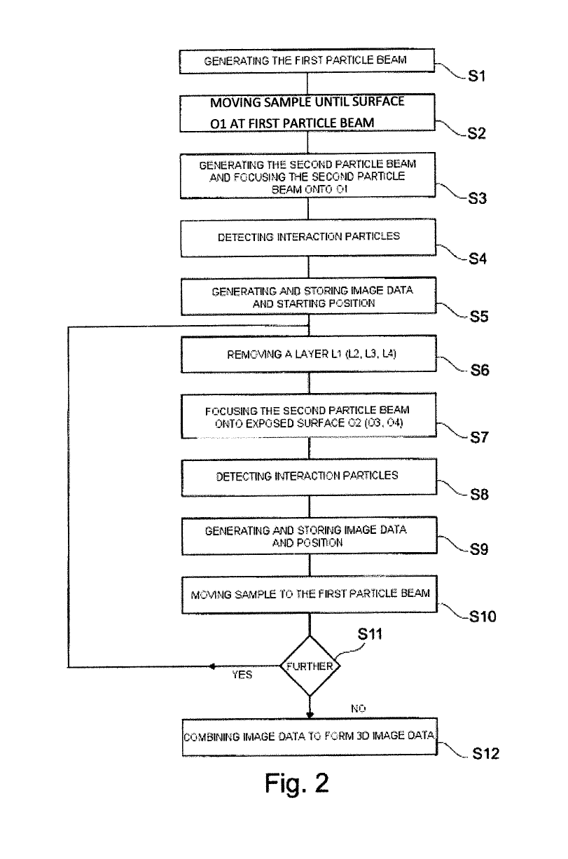

FIG. 2 shows a schematic illustration of a sequence of a first exemplary embodiment of a method according to the invention;

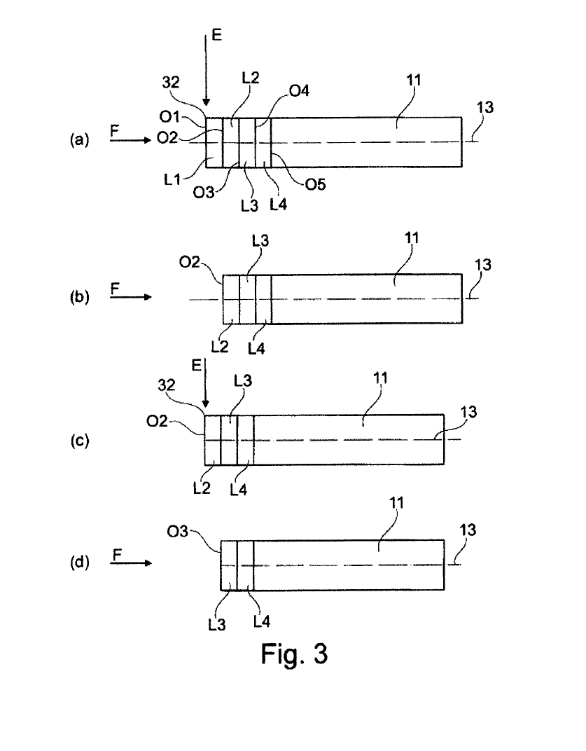

FIG. 3 shows schematic illustrations of individual method steps of the method in accordance with FIG. 2;

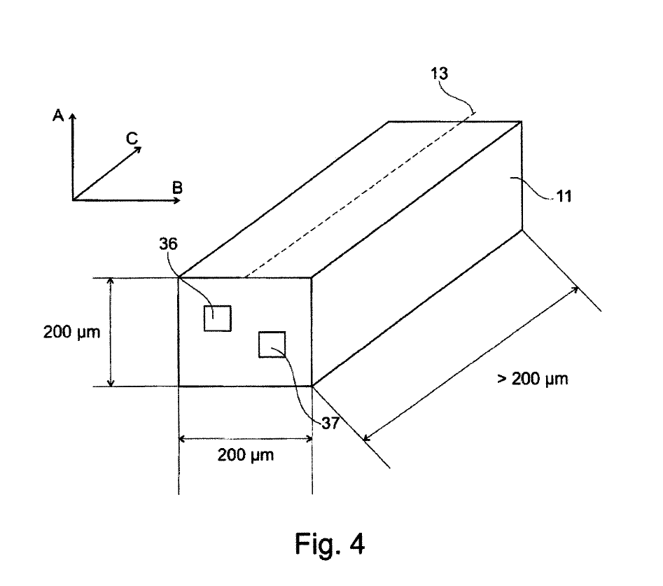

FIG. 4 shows a schematic illustration of a sample;

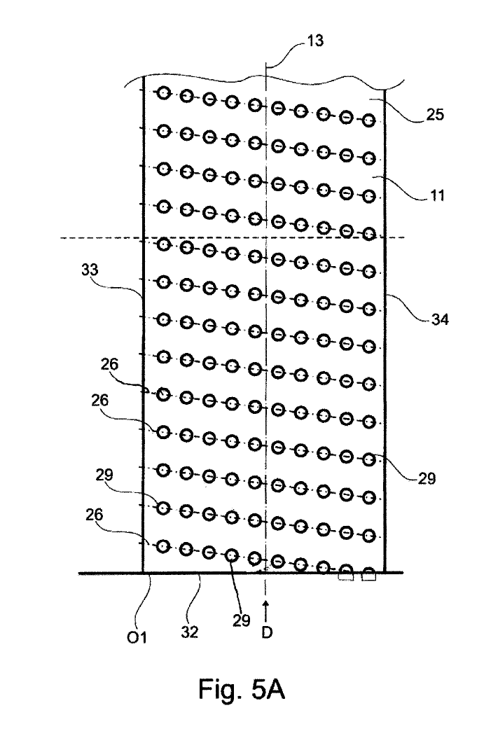

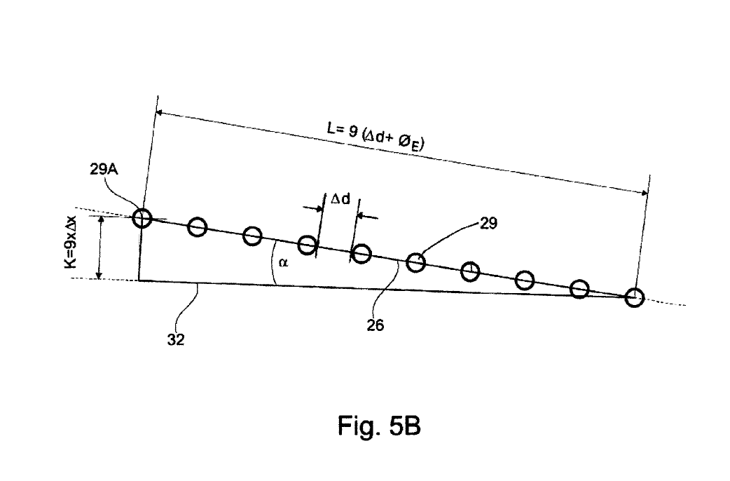

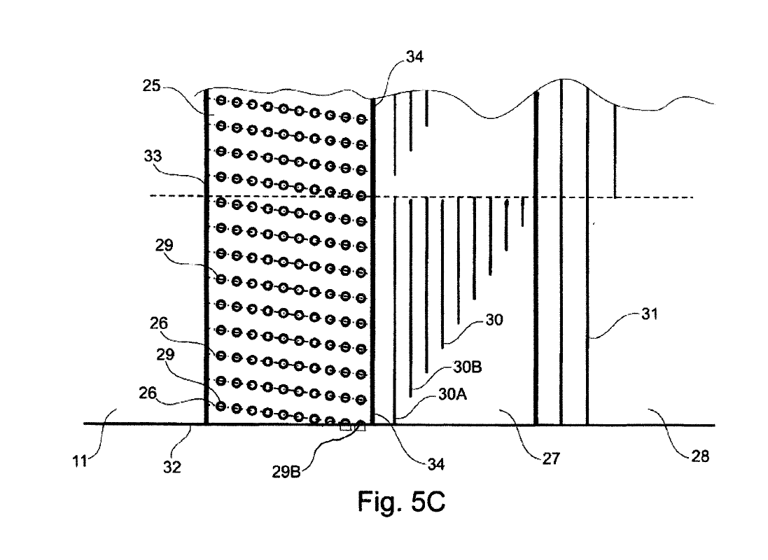

FIGS. 5A-C show schematic illustrations of the sample according to FIG. 4 with markings;

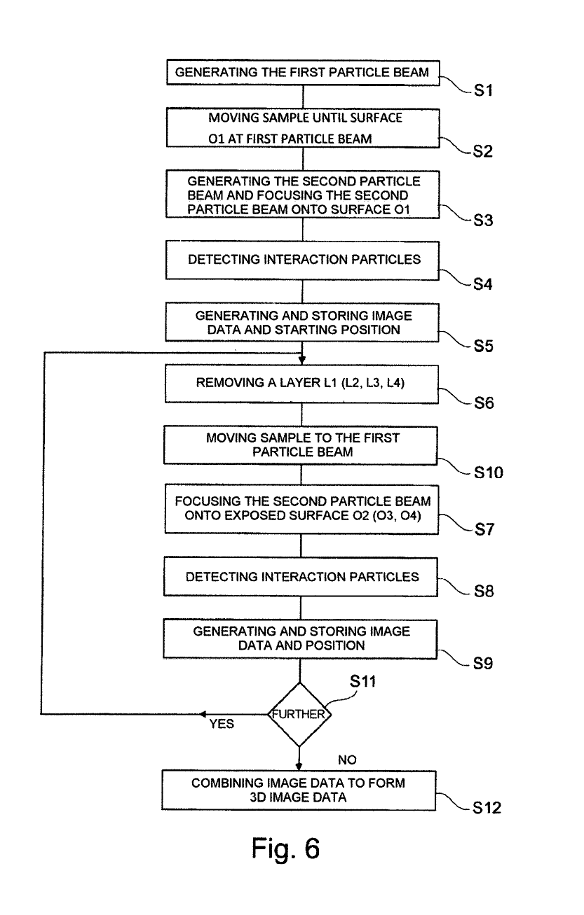

FIG. 6 shows a schematic illustration of a sequence of a further exemplary embodiment of a method according to the invention;

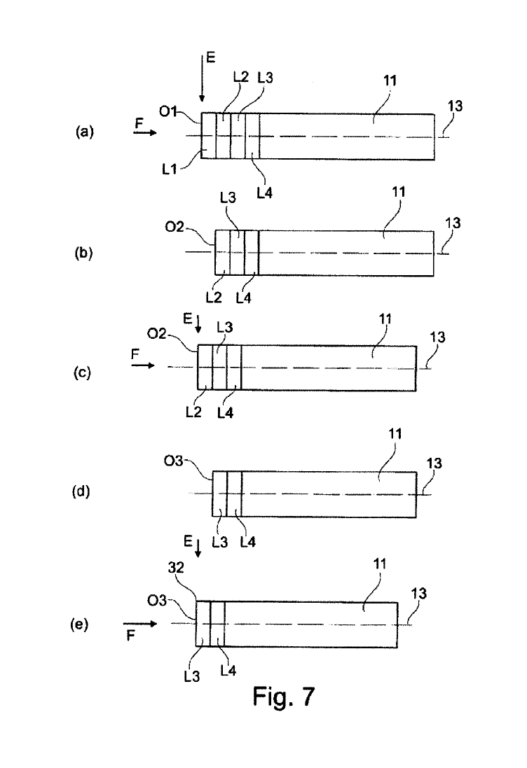

FIG. 7 shows schematic illustrations of individual method steps of the method in accordance with FIG. 6;

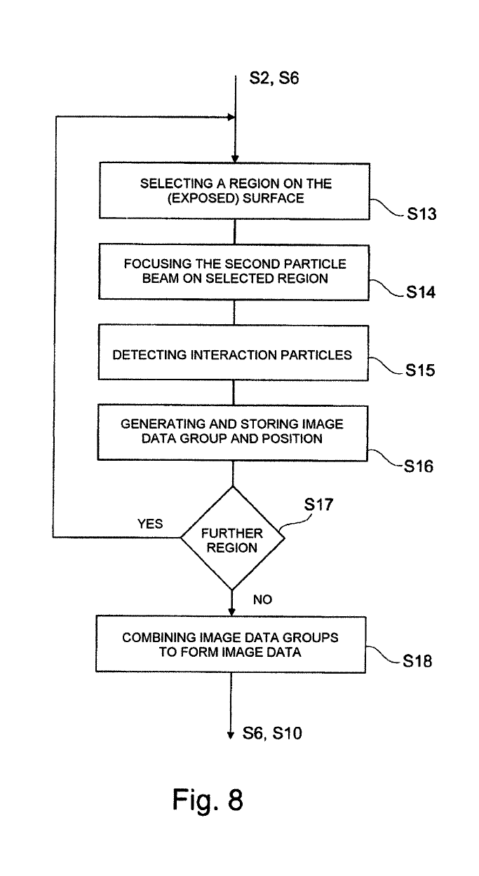

FIG. 8 shows a schematic illustration of a sequence of a further exemplary embodiment of the method in accordance with FIG. 2; and

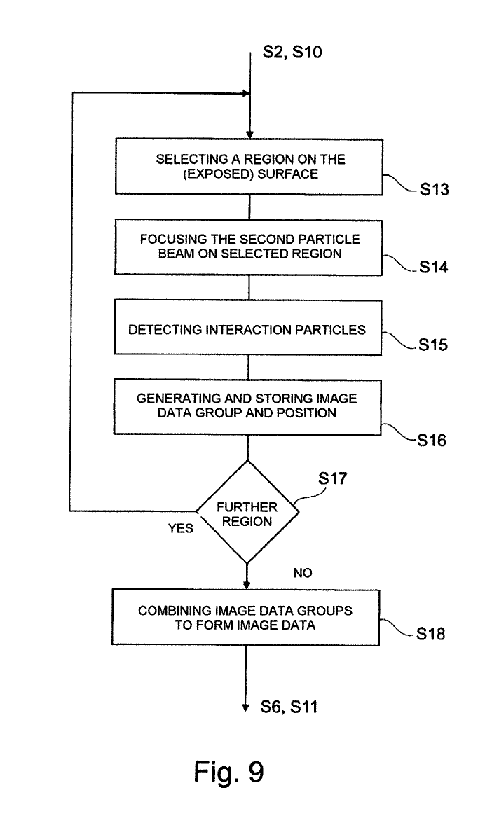

FIG. 9 shows a schematic illustration of a sequence of a further exemplary embodiment of the method in accordance with FIG. 6.

FIG. 1A shows a schematic illustration of a particle beam device having an ion beam device 1 and an electron beam device 24. The methods which are explained in greater detail further below are carried out using the particle beam device illustrated.

The ion beam device 1 has an ion beam column 2, in which numerous units of the ion beam device 1 are arranged. In particular, an ion source 3 is arranged in the ion beam column 2. The ion source 3 generates ions which form a first particle beam in the form of an ion beam in the ion beam column 2. By way of example, ions from an individual element (for example gallium (Ga)) are made available by means of the ion source 3. However, the ions can also be embodied as ionized atoms or as ionized molecules.

The ions are accelerated to a predeterminable potential by means of an ion beam electrode 4 and subsequently guided through a condenser lens 5. Afterward, the ion beam formed from the ions is guided through a diaphragm 7 and then passes to a first electrode arrangement 8 and to a second electrode arrangement 9, which are embodied as scanning electrodes. By means of the first electrode arrangement 8 and the second electrode arrangement 9, the ion beam consisting of the ions is scanned over a sample 11. Beforehand, the ion beam is focused onto the sample 11 by means of a first objective lens 10.

The sample 11 is arranged on a sample carrier 12, which ensures that the sample 11 is movable along an x-axis. The x-axis runs along a longitudinal axis 13 of the sample 11, as is illustrated in FIG. 1A. The longitudinal axis 13 of the sample 11 preferably lies in a first plane, which is arranged perpendicular or substantially perpendicular to a second plane, in which the first particle beam is fed to the sample 11.

The sample carrier 12 is illustrated in greater detail in FIG. 1B. The sample carrier 12 is embodied as a movable sample stage. It has a sample receptacle 12A, on which the sample 11 is arranged. The sample carrier 12 embodied as a sample stage has movement elements that ensure a movement of the sample carrier 12. The movement elements are illustrated schematically in FIG. 1B. The sample carrier 12 has a first movement element 38 on a housing 39 of a sample chamber, in which the sample carrier 12 is arranged and which is connected to the ion beam column 2 (not illustrated). The first movement element 38 enables the sample carrier 12 to be moved along a z-axis. Furthermore, a second movement element 40 is provided, which is embodied as a guide for a slide and ensures that the sample carrier 12 is movable in an x-direction. Furthermore, a third movement element 41 is provided. The third movement element 41 is embodied in such a way that the sample carrier 12 is movable in a y-direction.

The sample carrier 12 in turn is embodied with a fourth movement element 42, which enables the sample carrier to be rotatable about a first rotation axis R1. Furthermore, a fifth movement element 43 is provided, which enables the sample carrier 12 to rotate about a second rotation axis R2. The second rotation axis R2 is also designated as “tilt axis”, about which tilting of the sample 11 arranged in the sample carrier 12 by an angle γ is made possible.

In the exemplary embodiment illustrated in FIG. 1A, the sample carrier 12 is tilted by the angle γ by rotation about the second rotation axis R2. The sample 11 is movable by displacement along the x-direction in the direction of the longitudinal axis 13. Furthermore, in the exemplary embodiment illustrated here, the sample carrier 12 is, for example, also provided with a piezo-drive additionally for a further movement in the x-direction. On account of this embodiment, the sample carrier 12 can be moved relatively accurately, such that the sample 11 can assume a predeterminable position relatively well.

The electron beam device 24 is embodied as a scanning electron microscope. It has an electron column 16, in which the units of the electron beam device 24 are arranged. Thus, an electron source 17 is provided, which generates electrons that are extracted by means of a first electrode 18. By means of a second electrode 19, the electrons are accelerated to a predeterminable potential. The electrons are subsequently guided through a second condenser lens 20, whereby a second particle beam is shaped in the form of an electron beam. The latter is focused, by means of a second objective lens 21, onto a surface 14 of the sample 11 to be analyzed. Scanning electrodes (not illustrated) arranged at the second objective lens 21 ensure that the electron beam can be scanned over the sample 11.

When the electron beam impinges on the surface 14 of the sample 11, interaction particles, in particular secondary electrons and backscattered electrons, arise. These are detected by means of a first detector 22 and by means of a second detector 23 and are used for imaging. It is thus possible to generate an image of the surface 14 of the sample 11. The first detector 22 and the second detector 23 are connected to an evaluation and storage unit 15, in which image data of the surface 14 are analyzed and stored. Furthermore, the evaluation and storage unit 15 is provided with a processor, in which a program code of a computer program product is loaded, which executes the methods according to the invention. In further exemplary embodiments, furthermore, a third detector 23A can be provided (cf. FIG. 1A), which acquires further interaction reactions, for example x-ray quanta, which can likewise be used for generating image data.

The methods according to the invention can be carried out by means of the apparatus illustrated above. Said methods are based, in particular, on the fact that individual surfaces of a sample are exposed by means of the first particle beam (ion beam) and that images of the individual surfaces are generated by means of a second particle beam (electron beam).

FIG. 2 shows a schematic illustration of a first exemplary embodiment of a method according to the invention which can be carried out using the particle beam device illustrated in FIG. 1A. Individual method steps of this method are illustrated schematically in FIG. 3.

In the method illustrated in FIG. 2, a sample 11 is analyzed, which sample is embodied such that it is substantially rectangular. The sample 11 has a first extent in a first direction along an A-axis of substantially 200 μm and a second extent in a second direction along a B-axis of substantially 200 μm. A third extent of the sample 11 in a third direction along a C-axis is significantly greater than 200 μm (cf. FIG. 4). The C-axis is arranged parallel to the longitudinal axis 13 of the sample 11 (cf. FIG. 1). The A-axis, the B-axis and the C-axis are respectively perpendicular to one another (cf. FIG. 4).

Firstly, a method step S1 involves generating the first particle beam in the form of the ion beam. The first particle beam is made available by means of the ion beam device 1. In this case, the first particle beam is guided in arrow direction E in a plane arranged perpendicular to the longitudinal axis 13 of the sample 11 (also cf. FIG. 3a). The sample 11 is then moved in a direction along the x-axis (that is to say parallel to or along the longitudinal axis 13 of the sample 11) in the direction of the first particle beam (cf. FIG. 1A) until a first surface O1, which constitutes a boundary surface of the sample 11, lies substantially in the plane of the first particle beam (cf. FIG. 3a). This is identified by the fact that, upon the movement of the sample 11, a first edge 32 of the sample 11 impinges on the first particle beam and the matter at the first edge 32 interacts with the first particle beam. The interaction particles that arise in this case are detected. A rise in a detection signal determined by one of the abovementioned detectors above a predeterminable threshold value indicates that the first edge 32 has encountered the first particle beam. The position of the sample 11 set in this way is used as a starting position for the further performance of the method according to the invention and is stored in the evaluation and storage unit 15.

The starting position is determined accurately by means of markings being read out. FIG. 5A shows a schematic illustration of the sample 11 with markings. The illustration shows a view of the sample 11 from the direction from which the first particle beam in the form of the ion beam is guided onto the sample 11. The first particle beam thus runs into the plane of the drawing. The second particle beam in the form of the electron beam is guided in an arrow direction D onto the surface to be analyzed, which here is provided with the reference symbol O1 (first surface O1), of the sample 11. On account of the rectangular embodiment, the sample 11 has edges that delimit the spatial extent of the sample 11. Three of the edges of the sample 11 are illustrated in FIG. 5A, namely the first edge 32 already mentioned above, a second edge 33 and a third edge 34. As is illustrated in even greater detail further below, the first edge 32 of the sample 11 in each case adjoins that surface of the sample 11 (in FIG. 5A the first surface O1), which is exposed by means of the first particle beam and is subsequently analyzed by means of the second particle beam.

A plurality of line markings 26 are applied in a grating-type manner on a marking surface 25 of the sample 11, which is oriented substantially perpendicularly to the first particle beam. The line markings 26 are arranged parallel to one another and each have a multiplicity of individual markings 29 in the form of circular cutouts. In the exemplary embodiment illustrated, a total of ten individual markings 29 are provided in each of the line markings 26. Considerations have revealed that the diameter of each of the individual markings 29 can be greater than the desired resolution along the longitudinal axis 13 of the sample 11 (depth resolution). By way of example, the diameter of each of the individual markings 29, given a depth resolution of 5 nm, is substantially 25 nm. This is explained in detail below.

The individual line markings 26 are arranged at an angle with respect to the longitudinal axis 13 which is not 90°. Consequently, they do not run perpendicularly to the longitudinal axis 13 of the sample 11 and are therefore also arranged at a specific angle with respect to the first edge 32. FIG. 5B illustrates this. The illustration shows one of the line markings 26, which directly adjoins the first edge 32. Individual markings 29 adjacent to one another are arranged at a distance Δd with respect to one another. In this case, the distance Δd is chosen such that the distance Δd is greater than or equal to the diameter Ø_{E} of each of the individual markings 29. Consequently, Δd≧Ø_{E} holds true. The line marking 26 has the following length:

L=9×(Δd+Ø_{E}) [1]

The distance K between the individual marking 29A and the first edge 32 is calculated as follows:

K=9×Δx [2]

where Δx is the desired depth resolution. In the case of a predetermined desired depth resolution Δx and a predetermined diameter Ø_{E} and for Δd=Ø_{E}, it is possible to calculate the angle alpha at which the line marking 26 (and hence also all further line markings 26) are arranged with respect to the first edge 32:

$$sin α = \frac{K}{L} = \frac{9 \times Δ x}{9 \times ( Δ d + {}_{E} )} = \frac{Δ x}{( Δ d + {}_{E} )} = \frac{Δ x}{2 \times {}_{E}} \qquad [ 3 ]$$

Given a desired depth resolution Δx=5 nm and a diameter Ø_{E}=25 nm, a value of approximately 6° is obtained after solving [3] for alpha.

By means of the individual markings 29, it is possible to define and determine the abovementioned starting position from which the method according to the invention is further carried out.

FIG. 50 shows a further exemplary embodiment of the sample 11, which basically corresponds to the sample 11 in accordance with FIG. 5A, but which is additionally provided with further markings. Thus, the sample 11 in accordance with FIG. 5C is provided with the numerous line markings 26. Each of the line markings 26 has in each case ten individual markings 29. The line markings 26 are delimited by the first edge 32, the second edge 33 and the third edge 34. In addition, a first field 27 and a second field 28 are provided on the marking surface 25 of the sample 11. A first line structure 30 is provided in the first field 27, the individual lines (for example a first line 30A and a second line 30B) of which line structure have different lengths and are arranged parallel to one another. Each individual line of the first line structure 30 is assigned to a specific line marking 26. The second field 28 is also provided with a line structure, namely the second line structure 31. The latter also has individual lines which are arranged parallel to one another and can have different lengths. The individual markings 29 define a one-fold distance between an exposed surface and the starting position. By contrast, the first line structure 30 of the first field 27 defines a ten-fold distance between an exposed surface and the starting position. Furthermore, the second line structure 31 of the second field 28 defines the hundred-fold distance between an exposed surface and the starting position. This is explained in even greater detail further below.

All of the line markings 26, the individual markings 29 and also the first line structure 30 and also the second line structure 31 can be introduced into the sample 11 by means of the first particle beam or the second particle beam. In addition, it can be provided that the first individual markings 29 are provided with a contrast agent (for example platinum).

On the basis of the above-described line markings 26 and also the first line structure 30 and also the second line structure 31, it is now possible to accurately define the abovementioned starting position of the first surface O1. The starting position is used for calculating the relative position of further surfaces exposed by the method according to the invention, as is explained in even greater detail further below.

The determination of the starting position in the direction of the x-axis is effected after the generation of an image of the first surface O1 by means of the second particle beam in accordance with the method steps S3 to S5 of the method in accordance with FIG. 2. Firstly, the second particle beam is generated in the form of the electron beam by means of the electron beam device 24 and focused onto the first surface O1 of the sample 11, to be precise in arrow direction F (cf. FIG. 3a). The second particle beam is then scanned over the first surface O1 of the sample 11. The interaction particles (in particular secondary electrons and backscattered electrons) that arise upon the impingement of the second particle beam are detected by means of the first detector 22 and the second detector 23. If appropriate, x-ray quanta are also acquired by means of the third detector 23A. The detector signals provided by means of the first detector and the second detector 23 (if appropriate the third detector 23A) are used for imaging and thus for generating an image of the first surface O1. Image data associated with the first surface O1 are generated and stored in the evaluation and storage unit 15.

The image generated from the first surface O1 exhibits at least one of the individual markings 29, if appropriate also one of the lines of the first line structure 30 and/or of the second line structure 31. The individual markings 29 (if appropriate also the lines of the first line structure 30 and/or of the second line structure 31) on the first surface O1 identify the starting position. The latter is stored.

In a further method step S6, a first layer L1 containing the first surface O1 is then removed from the sample 11 by means of the first particle beam. In this exemplary embodiment, the thickness of the layer L1 is 15 nm. After the layer L1 has been removed, a second surface O2 is exposed, onto which the second particle beam is then focused (cf. FIG. 3b). The second particle beam is fed onto the second surface O2 in arrow direction F (method step S7). The interaction particles (in particular secondary electrons and backscattered electrons) and/or interaction reactions (for example x-ray quanta that arise) that arise upon the impingement of the second particle beam are detected by means of the first detector 22, by means of the second detector 23 and by means of the third detector 23A and are used for generating an image of the second surface O2 (method step S8). Consequently, image data are generated with regard to the second surface O2, and they are stored in the evaluation and storage unit 15 (method step S9). In addition, the position of the second surface O2 is determined and stored, as explained further below.

Afterward, in method step S10, the sample 11 is moved in the direction of the second particle beam (cf. FIG. 3c) until the first edge 32, which now adjoins the second surface O2, lies in the plane of the second particle beam (cf. explanations above). An interrogation is made as to whether an image of a further surface is to be generated (method step S11). If an image of a further surface is to be generated, then method steps S6 to S11 are correspondingly repeated, wherein, by way of example, a second layer L2, a third layer L3 and a fourth layer L4 are successively removed in order to expose a third surface O3, a fourth surface O4 and a fifth surface O5 and in order to generate an image of them in each case by means of the second particle beam.

An explanation is given below on the basis of an example of how the exact position of the exposed surfaces is determined. This is explained on the basis of an arbitrary surface. When a layer is removed from the sample 11 in order to expose the arbitrary surface, individual markings 29 of the line marking 26 become visible on the generated image of the arbitrary surface. Furthermore, lines of the first line structure 30 and of the second line structure 31 also become visible. By way of example, the markings and structures illustrated in FIG. 5C are visible after the arbitrary surface has been exposed: individual marking 29B, the line 30A of the first line structure 30 and also two lines of the second line structure 31. The position of the arbitrary surface with respect to the starting position can now be determined by simple reading. As mentioned above, the individual marking 29 reproduces a 1-fold distance from the starting position. Since only the first individual marking 29B can be seen, this is deemed to be the value zero. By contrast, a 10-fold distance is available on account of the line 30A of the first line structure and two 100-fold distances are available on account of the two lines of the second line structure 31. The distance between the arbitrary surface and the starting position is therefore:

210×Δx=210×5 nm=1050 nm

If, in method step S11, it is decided that no image of a further surface is to be generated, in method step S12 the stored image data are combined taking account of the stored positions to form a three-dimensional image data record of the sample 11. The three-dimensional image data record is then represented in the form of an image on a display unit, for example a monitor.

The abovementioned method makes it possible for exposed surfaces (apart from the first surface O1) to be situated at the same position relative to the first particle beam and the second particle beam. Accordingly, it suffices to focus the first particle beam and/or the second particle beam initially once onto an actually exposed surface (for example the second surface O2) of the sample 11. Since all further exposed surfaces are always arranged at the same position, it is no longer necessary to refocus the first particle beam and/or the second particle beam. Moreover, possible distortions and further imaging aberrations (for example astigmatism) at the further exposed surfaces are constant at the same position and therefore do not have to be subsequently corrected.

FIG. 6 shows a schematic illustration of a further exemplary embodiment of a method according to the invention which can be carried out using the particle beam device illustrated in FIG. 1. The individual method steps of this method are illustrated schematically in FIG. 7.

The exemplary embodiment illustrated in FIG. 6 is fundamentally based on the exemplary embodiment explained above. Thus, method steps S1 to S6 of the method in accordance with FIG. 6 correspond to method steps S1 to S6 of the method in accordance with FIG. 2, and so, with regard to these method steps, reference is made to the explanations given further above. FIGS. 7a and 7b therefore correspond to FIGS. 3a and 3b.

The further method steps S7 to S12 of the method in accordance with FIG. 6 also basically correspond to method steps S7 to S12 of the method in accordance with FIG. 2, although with the difference that method step S10 takes place between method step S6 and method step S7. Thus, the movement of the sample 11 to the first particle beam is always effected after the removal of a layer. In this position, the second particle beam is then focused onto the exposed surface, such that imaging can be effected by detection of interaction particles (also cf. FIG. 7c). The generated image data and the position of the exposed surface are stored in the evaluation and storage unit 15. The position is determined in the manner already explained above.

Should it be stipulated in method step S11 that further surfaces are to be exposed and images of these further surfaces are to be generated, method steps S6 to S11 are repeated. This is illustrated schematically in FIGS. 7d and 7e. FIG. 7d shows the sample 11 in which the second layer L2 has been removed, such that a third surface O3 has been exposed. The sample 11 is then moved in such a manner until the first edge 32 arrives at the first particle beam. In this position, an image of the third surface O3 is generated.

In this exemplary embodiment, too, an exposed surface is situated at the same position relative to the first particle beam and the second particle beam. Consequently, it suffices to focus the first particle beam and/or the second particle beam initially once onto a surface of the sample. Since all further exposed surfaces are always arranged at the same position, it is no longer necessary to refocus the first particle beam and/or the second particle beam. Moreover, possible distortions and further imaging aberrations (for example astigmatism) at the further exposed surfaces are constant at the same position and therefore do not have to be subsequently corrected.

A modification of the method according to FIG. 2 is illustrated in FIG. 8. In this exemplary embodiment, after method step S2 a method step S13 is effected, in which a region on the first surface O1 is selected. This is a first region 36, for example, which is illustrated schematically in FIG. 4. In a further method step S14, the second particle beam is then focused onto the first region 36. The interaction particles and/or interaction reactions that arise when the second particle beam impinges on the first region 36 are detected and used for imaging (method step S15). Data of a first image data group are generated and stored in the evaluation and storage unit 15, which data then reproduce an imaging of the first region 36 (method step S16). Furthermore, the exact position of the selected region is stored in the evaluation and storage unit 15. A further method step S17 involves determining whether method steps S13 to S16 are to be carried out for a further region on the first surface O1 of the sample 11, for example a second region 37 (cf. FIG. 4). If this is answered in the affirmative, then method steps S13 to S16 are repeated for the second region 37. In this case, a second image data group is generated, which serves for generating an image of the second region 37. The second image data group is likewise stored in the evaluation and storage unit 15. The position of the second region 37 is stored (see above).

If a further region is no longer to be measured, then the image data groups stored in the evaluation and storage unit 15 (in the present example the first image data group and the second image data group) are combined in a mosaic-like manner to form image data of the first surface O1 in such a way that the combined image data reproduce a complete image of the first surface O1 (method step S18). Afterward, method step S6 and all further method steps are then carried out.

The exemplary embodiment illustrated in FIG. 8 is also suitable for the mosaic-like combination of any surface exposed in the method in accordance with FIG. 2, that is to say, for example, the second surface O2 or the third surface O3. For this, after method step S6, method steps S13 to S18 described above are carried out. Afterward, method step S10 and all further method steps are carried out.

A modification of the method according to FIG. 6 is illustrated in FIG. 9. This modification basically corresponds to the modification according to FIG. 8, wherein method steps S13 to S18 are carried out between method step S2 and method step S6 or method step S10 and method step S11.

The acquisition of image data groups in accordance with the abovementioned exemplary embodiments is effected for the reasons outlined above.

Besides displacing the position of the second particle beam, it is also possible to move the sample carrier for mosaic-like image recording in the plane of the surface 14 (cf. FIG. 1A). This can be achieved, for example, by moving the sample 11 in the y-direction and/or z-direction (cf. FIG. 1A). In this case, it is provided that image data groups are acquired at different locations. In this way, by way of example, the first image data group and the second image data group are determined. The individual recordings of the different image data groups are subsequently combined to form an entire image.

In a further exemplary embodiment of the method in accordance with FIGS. 8 and 9, method step S14 involves additionally reading out at least one correction value from a correction map in a manner dependent on the position of the second particle beam, in order possibly to correct the focusing of the second particle beam on the surface to be imaged. This is advantageous during the mosaic-like combination since the focusing of the second particle beam during scanning over a larger surface can indeed vary somewhat. However, this variation is so small that the second particle beam need not necessarily be refocused. Rather, the acquired image data are corrected computationally by means of the correction value.

As already mentioned above, in the exemplary embodiment illustrated in FIG. 1A, the sample carrier 12 can also be provided with a piezo-drive additionally for a further movement in the x-direction. However, the invention is not restricted to a piezo-drive. Rather, any vernier drive can be used. Said piezo-drive serves for precise and continuous movement of the sample 11 in the x-direction. This exemplary embodiment can be combined for example with one of the methods mentioned above. The piezo-drive enables continuous tracking of the sample 11. By way of example, the sample 11 is brought into a specific position by means of the sample carrier 12 and from there is brought into a final position by means of the piezo-drive, said final position serving for example as the starting position described above. From this position, the sample 11 is moved further by means of the piezo-drive. As an alternative to this, however, consideration is also given to moving the sample 11 continuously. Thus, provision is made, for example, for carrying out steps S6 and S10 in FIG. 6 simultaneously. During the removal of the layer L1 (or L2, L3 and L4), the sample 11 is slowly advanced by means of the piezo-drive, while the first particle beam removes the advanced layer of the sample 11.

### LIST OF REFERENCE SYMBOLS

1 Ion beam device
2 Ion beam column
3 Ion source
4 Ion beam electrode
5 First condenser lens
6
7 Diaphragm
8 First electrode arrangement
9 Second electrode arrangement
10 First objective lens
11 Sample
12 Sample carrier
13 Longitudinal axis
14 Surface
15 Evaluation and storage unit
16 Electron column
17 Electron source
18 First electrode
19 Second electrode
20 Second condenser lens
21 Second objective lens
22 First detector
23 Second detector
23A Third detector
24 Electron beam device
25 Marking surface
26 Line marking
27 First field
28 Second field
29 Individual marking
30 First line structure
31 Second line structure
32 First edge
33 Second edge
34 Third edge
35
36 First region
37 Second region
38 First movement element
39 Housing
40 Second movement element
41 Third movement element
42 Fourth movement element
43 Fifth movement element
R1 First rotation axis
R2 Second rotation axis
O1 First surface
O2 Second surface
O3 Third surface
O4 Fourth surface
O5 Fifth surface
L1 First layer
L2 Second layer
L3 Third layer
L4 Fourth layer

1. A method for generating three-dimensional image data of a sample, comprising:
moving a sample arranged on a sample carrier, which is embodied in movable fashion, using the sample carrier in the direction of a longitudinal axis of the sample;
feeding a first particle beam to the sample;
removing a first layer from the sample using the first particle beam, such that a first surface of the sample is exposed;
feeding a second particle beam, which is focused onto the first surface of the sample;
acquiring first image data of the sample by detecting interaction particles or interaction reactions that arise as a result of feeding the second particle beam onto the first surface of the sample;
storing the first image data;
removing a second layer of the sample using the first particle beam, wherein the second layer has the first surface and whereby a second surface of the sample is exposed;
feeding the second particle beam onto the second surface of the sample;
acquiring second image data of the sample by detecting interaction particles or interaction reactions that arise as a result of feeding the second particle beam onto the second surface of the sample;
storing the second image data; and
calculating three-dimensional image data of the sample using the first image data and the second image data,
wherein, in the course of acquiring the first image data, at least one first image data group and at least one second image data group are acquired, wherein the first image data group is assigned to a first region of the first surface, wherein the second image data group is assigned to a second region of the first surface, and wherein the first image data group and the second image data group are combined in a mosaic-like manner to form the first image data.

2. The method as claimed in claim 1, further comprising:
moving the sample arranged on the sample carrier, which is embodied in movable fashion, using the sample carrier in the direction of the longitudinal axis of the sample to a first predeterminable position of the sample;
feeding the first particle beam to the sample;
removing the first layer from the sample using the first particle beam, such that the first surface of the sample is exposed;
feeding the second particle beam, which is focused onto the first surface of the sample;
acquiring the first image data of the sample by detecting interaction particles or interaction reactions that arise as a result of feeding the second particle beam onto the first surface of the sample;
storing the first image data;
moving the sample in the direction of the longitudinal axis of the sample using the sample carrier into a second predeterminable position of the sample;
removing the second layer of the sample using the first particle beam, wherein the second layer has the first surface and whereby the second surface of the sample is exposed;
feeding the second particle beam onto the second surface of the sample;
acquiring the second image data of the sample by detecting interaction particles or interaction reactions that arise as a result of feeding the second particle beam onto the second surface of the sample;
storing the second image data; and
calculating the three-dimensional image data of the sample using the first image data and the second image data.

3. The method as claimed in claim 1, further comprising:
feeding the first particle beam to the sample arranged on the sample carrier embodied in movable fashion;
removing the first layer from the sample using the first particle beam, such that the first surface of the sample is exposed;
moving the sample using the sample carrier in the direction of the longitudinal axis of the sample to a first predeterminable position of the sample;
feeding the second particle beam, which is focused onto the first surface of the sample;
acquiring the first image data of the sample by detecting the interaction particles or interaction reactions that arise as a result of feeding the second particle beam onto the first surface of the sample;
storing the first image data;
removing the second layer of the sample using the first particle beam, wherein the second layer has the first surface and whereby the second surface of the sample is exposed;
moving the sample in the direction of the longitudinal axis of the sample using the sample carrier into a second predeterminable position of the sample;
feeding the second particle beam onto the second surface of the sample;
acquiring the second image data of the sample by detecting the interaction particles or the interaction reactions that arise as a result of feeding the second particle beam onto the second surface of the sample;
storing the second image data; and
calculating the three-dimensional image data of the sample using the first image data and the second image data.

4. The method as claimed in claim 1, wherein the sample arranged on the sample carrier embodied in movable fashion is moved continuously, and wherein the first layer or the second layer of the sample is removed using the first particle beam simultaneously during the movement.

5. The method as claimed in claim 2, further comprising at least one of the following:
(i) storing the first predeterminable position; or
(ii) storing the second predeterminable position.

6. The method as claimed in claim 1, wherein a layer thickness to be removed of at least one of: the first layer or the second layer is predetermined.

7. The method as claimed in claim 2, wherein an identical position is predetermined as the first predeterminable position and as the second predeterminable position.

8. The method as claimed in claim 1, wherein at least one of the following is further provided:
(i) the first particle beam is fed in a plane arranged perpendicular to the longitudinal axis of the sample, and wherein the first particle beam is scanned over the sample; or
(ii) the second particle beam is scanned over at least one of: the first surface or the second surface.

9. (canceled)

10. The method as claimed in claim 1, wherein, in the course of acquiring the second image data, at least one third image data group and at least one fourth image data group are acquired, wherein the third image data group is assigned to a third region of the second surface, wherein the fourth image data group is assigned to a fourth region of the second surface, and wherein the third image data group and the fourth image data group are combined in a mosaic-like manner to form the second image data.

11. The method as claimed in claim 1, wherein the second particle beam is guided to at least one of: a first beam position on a first surface region or a second beam position on a second surface region, and wherein the method further comprises:
reading-out of at least one first correction value from a correction map, wherein the reading-out is effected in a manner dependent on at least one of: the first beam position or the second beam position, in order to correct the focusing of the first particle beam on the first surface region or the second surface region.

12. The method as claimed in claim 2, further comprising:
providing at least one first marking running non-parallel to the longitudinal axis of the sample; and
determining at least one of: the first predeterminable position or the second predeterminable position using the first marking.

13. The method as claimed in claim 12, wherein providing the first marking comprises providing a first marking having a plurality of punctiform or hole-type individual markings, wherein the punctiform or hole-type individual markings are arranged in a line-like manner.

14. The method as claimed in claim 12, further comprising:
providing at least one second marking running parallel to the longitudinal axis; and
determining at least one of: the first predeterminable position or the second predeterminable position using the second marking.

15. The method as claimed in claim 14, wherein at least one of: the first marking or the second marking is provided with a contrast agent.

16. The method as claimed in with claim 7, wherein at least one of the first predeterminable position or the second predeterminable position is determined as follows:
providing the first particle beam in the plane;
detecting interaction particles or interaction reactions that arise on account of the interaction of the first particle beam with matter; and
moving the sample along the longitudinal axis of the sample using the sample carrier until a predeterminable threshold value is exceeded in the course of detecting interaction particles.

17. The method as claimed in claim 1, wherein at least one of the following is provided:
(i) an ion beam is fed as the first particle beam, or
(ii) an electron beam is fed as the second particle beam.

18. A computer program product comprising a non-transitory computer readable medium storing executable program code which, when executed in a computer processor, executes a method for generating three-dimensional image data of a sample, the method comprising:
moving a sample arranged on a sample carrier, which is embodied in movable fashion, using the sample carrier in the direction of a longitudinal axis of the sample;
feeding a first particle beam to the sample;
removing a first layer from the sample using the first particle beam, such that a first surface of the sample is exposed;
feeding a second particle beam, which is focused onto the first surface of the sample;
acquiring first image data of the sample by detecting interaction particles or interaction reactions that arise as a result of feeding the second particle beam onto the first surface of the sample;
storing the first image data;
removing a second layer of the sample using the first particle beam, wherein the second layer has the first surface and whereby a second surface of the sample is exposed;
feeding the second particle beam onto the second surface of the sample;
acquiring second image data of the sample by detecting interaction particles or interaction reactions that arise as a result of feeding the second particle beam onto the second surface of the sample;
storing the second image data; and
calculating three-dimensional image data of the sample using the first image data and the second image data,
wherein, in the course of acquiring the first image data, at least one first image data group and at least one second image data group are acquired, wherein the first image data group is assigned to a first region of the first surface, wherein the second image data group is assigned to a second region of the first surface, and wherein the first image data group and the second image data group are combined in a mosaic-like manner to form the first image data.

19. A sample which can be examined in a particle beam device, comprising:
a longitudinal axis; and
at least one first marking running non-parallel to the longitudinal axis of the sample, wherein the first marking has a plurality of punctiform or hole-type individual markings arranged in a line-like manner.

20. The sample as claimed in claim 19, further comprising:
at least one second marking which runs parallel to the longitudinal axis of the sample, wherein the first marking and the second marking serve for determining a distance of the sample from a starting position.

21. The sample as claimed in claim 19, wherein the individual markings have a diameter of 10 nm to 100 nm.

22. The sample as claimed in claim 20, wherein at least one of: the first marking or the second marking is provided with a contrast agent.

23. A particle beam device, comprising:
at least one sample carrier for receiving a sample, wherein the sample carrier is embodied in movable fashion;
at least one first beam generator that generates a first particle beam;
at least one second beam generator that generates a second particle beam,
at least one first objective lens that focuses the first particle beam onto the sample;
at least one second objective lens that focuses the second particle beam onto the sample;
at least one control unit in which a computer program product is loaded, the computer program product having executable code that performs a method for generating three-dimensional image data of the sample, the method comprising:
moving the sample arranged on the sample carrier, which is embodied in movable fashion, using the sample carrier in the direction of a longitudinal axis of the sample;
feeding the first particle beam to the sample;
removing a first layer from the sample using the first particle beam, such that a first surface of the sample is exposed;
feeding the second particle beam, which is focused onto the first surface of the sample;
acquiring first image data of the sample by detecting interaction particles or interaction reactions that arise as a result of feeding the second particle beam onto the first surface of the sample;
storing the first image data;
removing a second layer of the sample using the first particle beam, wherein the second layer has the first surface and whereby a second surface of the sample is exposed;
feeding the second particle beam onto the second surface of the sample;
acquiring second image data of the sample by detecting interaction particles or interaction reactions that arise as a result of feeding the second particle beam onto the second surface of the sample;
storing the second image data; and
calculating three-dimensional image data of the sample using the first image data and the second image data,
wherein, in the course of acquiring the first image data, at least one first image data group and at least one second image data group are acquired, wherein the first image data group is assigned to a first region of the first surface, wherein the second image data group is assigned to a second region of the first surface, and wherein the first image data group and the second image data group are combined in a mosaic-like manner to form the first image data.

24. The sample as claimed in claim 21, wherein the diameter of the individual markings is in a range of 15 nm to 60 nm.

25. The method as claimed in claim 3, further comprising at least one of the following:
(i) storing the first predeterminable position; or
(ii) storing the second predeterminable position.

26. The method as claimed in claim 3, wherein an identical position is predetermined as the first predeterminable position and as the second predeterminable position.

27. The method as claimed in claim 26, wherein the identical position is a position of the sample in which the first particle beam impinges on an edge of the sample, said edge being arranged substantially perpendicular to the longitudinal axis of the sample.

28. The method as claimed in claim 3, further comprising:
providing at least one first marking running non-parallel to the longitudinal axis of the sample; and
determining at least one of: the first predeterminable position or the second predeterminable position using the first marking.

29. The method as claimed in claim 28, wherein the at least one first marking is line-like.

30. The method as claimed in claim 28, wherein providing the first marking comprises providing a first marking having a plurality of punctiform or hole-type individual markings, wherein the punctiform or hole-type individual markings are arranged in a line-like manner.

31. The method as claimed in claim 28, further comprising:
providing at least one second marking running parallel to the longitudinal axis; and
determining at least one of the first predeterminable position or the second predeterminable position using the second marking.

32. The method as claimed in claim 31, wherein at least one of: the first marking or the second marking is provided with a contrast agent.

33. The method as claimed in claim 7, wherein the identical position is a position of the sample in which the first particle beam impinges on an edge of the sample, said edge being arranged substantially perpendicular to the longitudinal axis of the sample.

34. The method as claimed in claim 12, wherein the at least one first marking is line-like.
